(19) United States
(12) Patent Application Publication
(10) Pub. No.: US 2021/0193805 A1
(43) Pub. Date: Jun. 24, 2021

(54) LATERAL TRANSISTOR WITH LATERAL CONDUCTIVE FIELD PLATE OVER A FIELD PLATE POSITIONING LAYER

(71) Applicant: Monolithic Power Systems, Inc., San Jose, CA (US)

(72) Inventors: Ji-Hyoung Yoo, Los Gatos, CA (US); Yanjie Lian, Chengdu (CN); Daping Fu, Chengdu (CN); Xin Zhang, Chengdu (CN); Joel McGregor, Kirkland, WA (US); Jeesung Jung, San Ramon, CA (US); Jin Xing, Chengdu (CN); Xiaogang Wang, Chengdu (CN); Haifeng Yang, Shanghai (CN)

(21) Appl. No.: 16/719,978

(22) Filed: Dec. 18, 2019

(51) Int. Cl. H01L 29/40; H01L 29/78; H01L 29/08

(52) U.S. Cl. CPC H01L 29/404; H01L 29/0852; H01L 29/7816

(57) ABSTRACT

The present disclosure discloses a lateral transistor having a source region, a drain region, a gate near the source region side and a field dielectric positioned in or atop a portion of a well region between the drain region and the gate. The lateral transistor further includes a non-conductive field plate positioning layer positioned atop a portion of the field dielectric and separated laterally from the gate with a first lateral distance, a lateral conductive field plate positioned atop the non-conductive field plate positioning layer and separated laterally from the gate with a second lateral distance and a vertical trenched field plate contact extending vertically from a top surface of an interlayer dielectric layer through the interlayer dielectric layer to reach and contact with the lateral conductive field plate.

### TECHNICAL FIELD

This disclosure relates generally to semiconductor devices, and particularly but not exclusively relates to lateral high voltage transistors.

### BACKGROUND

Power transistors, such as double diffused metal-oxide semiconductor (DMOS) transistors are widely used in various power management applications, including used as power switching elements in power supplies for industrial and consumer electronic devices. In most modern applications, smaller power transistors with high current and high power handling capacity are desired in a smaller package. Hence, research trend has been focused on reducing the size and on resistance while enhancing the breakdown voltage of power transistors.

### SUMMARY

In accordance with an embodiment of the present disclosure, a lateral transistor with lateral conductive field plate over a field plate positioning layer is disclosed. The lateral transistor may comprise: a semiconductor layer of a first conductivity type; a well region of a second conductivity type opposite to the first conductivity type formed in the semiconductor layer; a source region of the second conductivity type formed in the semiconductor layer and separated from the well region by a body region; a drain region of the second conductivity type formed in the well region and separated from the source region; a gate positioned atop the semiconductor layer near the source region side; a field dielectric positioned in or atop a portion of the well region between the drain region and the gate; a non-conductive field plate positioning layer positioned atop a portion of the field dielectric and separated laterally from the gate with a first lateral distance, wherein the non-conductive field plate positioning layer has different etching characteristics from the field dielectric; a lateral conductive field plate positioned atop the non-conductive field plate positioning layer and separated laterally from the gate with a second lateral distance; an interlayer dielectric layer coating the semiconductor layer and the structures in/atop the semiconductor layer, wherein the interlayer dielectric layer has different etching characteristics from the lateral conductive field plate; and a vertical trenched field plate contact extending vertically from a top surface of the interlayer dielectric layer through the interlayer dielectric layer to reach and contact with the lateral conductive field plate.

In accordance with an embodiment of the present disclosure, the non-conductive field plate positioning layer may have a positioning layer vertical thickness configured to adjust a field plate to semiconductor height, and wherein the field plate to semiconductor height is a vertical distance from a bottom surface of the lateral conductive field plate to a semiconductor top surface of the semiconductor layer located under the lateral conductive field plate.

In accordance with an embodiment of the present disclosure, the positioning layer vertical thickness may range from 300 Å to 3000 Å. Yet in an alternative embodiment, the positioning layer vertical thickness may range from 500 Å to 2000 Å

In accordance with an embodiment of the present disclosure, the non-conductive field plate positioning layer may comprise a non-conductive layer formed of a non-conductive nitride layer group or a non-conductive carbide layer group or a nitride oxide compound layer group, or formed of a multilayer containing two or more from a non-conductive nitride layer group, a non-conductive carbide layer group and a nitride oxide compound layer group.

In accordance with an embodiment of the present disclosure, the second lateral distance is larger or equal to the first lateral distance. In an embodiment, the first lateral distance may range from 0.05 μm˜0.45 μm. In an embodiment, the second lateral distance may range from 0.1 μm˜0.5 μm.

In accordance with an embodiment of the present disclosure, the gate may comprise a gate dielectric layer and a gate conduction layer sitting on the gate dielectric layer.

In accordance with an embodiment of the present disclosure, the lateral conductive field plate may have the same composition and the same vertical thickness as the gate conduction layer.

In accordance with an embodiment of the present disclosure, the lateral conductive field plate may have a field plate vertical thickness ranges from 100 Å to 200 Å.

In accordance with an embodiment of the present disclosure, the lateral conductive field plate may be formed of doped poly-silicon. In an alternative embodiment, the lateral conductive field plate may be formed of metal nitride. In an alternative embodiment, the lateral conductive field plate may be formed of metal carbide.

In accordance with an embodiment of the present disclosure, the lateral conductive field plate and the non-conductive field plate positioning layer have the same pattern and lateral size.

In accordance with an embodiment of the present disclosure, the lateral conductive field plate and the non-conductive field plate positioning layer may have the same/similar etching characteristics and share a same dedicated mask during an etching process to pattern and form both the lateral conductive field plate and the non-conductive field plate positioning layer.

In accordance with an embodiment of the present disclosure, the lateral conductive field plate may be formed of a conductive nitride layer, and wherein the non-conductive field plate positioning layer is formed of a non-conductive nitride layer and/or a non-conductive carbide layer.

In accordance with an embodiment of the present disclosure, the lateral conductive field plate is omitted, and the vertical trenched field plate contact may vertically extend to reach and contact with the non-conductive field plate positioning layer. The non-conductive field plate positioning layer is etching selective over both the field dielectric and the interlayer dielectric layer to an etchant. In accordance with an embodiment of the present disclosure, a first partial layer which constitutes part of the interlayer dielectric layer may be formed before forming the non-conductive field plate positioning layer, and the non-conductive field plate positioning layer may sit atop a portion of the first partial layer laterally located between the drain region and the gate.

In accordance with an embodiment of the present disclosure, the non-conductive field plate positioning layer is omitted, and wherein a first partial layer which constitutes part of the interlayer dielectric layer is formed before forming the lateral conductive field plate, and wherein the lateral conductive field plate sits atop a portion of the first partial layer laterally located between the drain region and the gate.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features. Likewise, the relative sizes of elements illustrated by the drawings may differ from the relative size depicted.

FIG. 1 illustrates a cross-sectional view of a lateral transistor 100 in accordance with an embodiment of the present invention.

FIG. 2 illustrates a cross-sectional view of a lateral transistor 100 in accordance with an alternative embodiment of the present invention.

FIG. 3 illustrates a cross-sectional view of a lateral transistor 100 in accordance with an alternative embodiment of the present invention.

FIG. 4 illustrates a cross-sectional view of a lateral transistor 100 in accordance with an alternative embodiment of the present invention.

FIG. 5 illustrates a cross-sectional view of a lateral transistor 100 in accordance with an alternative embodiment of the present invention.

FIG. 6 illustrates a cross-sectional view of a lateral transistor 100 in accordance with an alternative embodiment of the present invention.

FIG. 7 illustrates a corresponding top plan view of the lateral transistor 100 shown in FIG. 1.

FIG. 8 illustrates a cross-sectional view of the lateral transistor 100 shown in FIG. 1 with the lateral conductive field plate 108 omitted in accordance with an embodiment of the present invention.

FIG. 9 illustrates a cross-sectional view of an exemplary variant of the lateral transistor 100 shown in FIG. 8 in accordance with an embodiment of the present invention.

FIG. 10 illustrates a corresponding top plan view of the lateral transistor 100 shown in FIG. 8 in accordance with an embodiment of the present invention.

FIG. 11 illustrates a cross-sectional view of the lateral transistors 100 shown in FIG. 1 with the non-conductive field plate positioning layer 107 omitted in accordance with an embodiment of the present invention.

The use of the same reference label in different drawings indicates the same or like components or structures with substantially the same functions for the sake of simplicity.

### DETAILED DESCRIPTION

Various embodiments of the present invention will now be described. In the following description, some specific details, such as example device structures, example manufacturing process and manufacturing steps, and example values for the process, are included to provide a thorough understanding of the embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the terms “left,” right,” “in,” “out,” “front,” “back,” “up,” “down, “top,” “atop”, “bottom,” “over,” “under,” “overlying,” “underlying,” “above,” “below” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The term “coupled,” as used herein, is defined as directly or indirectly connected in an electrical or non-electrical manner to establish an electrical relationship between the elements that are coupled. The terms “a,” “an,” and “the” includes plural reference, and the term “in” includes “in” and “on”. The phrase “in one embodiment,” as used herein does not necessarily refer to the same embodiment, although it may. The term “or” is an inclusive “or” operator, and is equivalent to the term “and/or” herein, unless the context clearly dictates otherwise. Those skilled in the art should understand that the meanings of the terms identified above do not necessarily limit the terms, but merely provide illustrative examples for the terms.

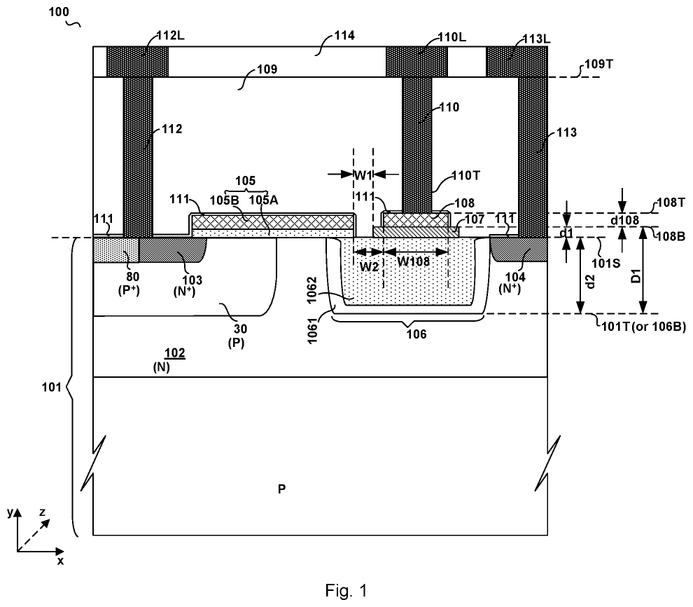

FIG. 1 illustrates a cross-sectional view of a lateral transistor 100 in accordance with an embodiment of the present invention. The cross-section is cut from a plane defined by the x and y axis. Throughout this disclosure, lateral refers to a direction parallel to the x axis while vertical refers to a direction parallel to the y axis. The lateral transistor 100 may comprise a semiconductor layer 101 of a first conductivity type (e.g. P-type in FIG. 1); a well region 102 of a second conductivity type (e.g. N-type in FIG. 1) opposite to the first conductivity type formed in the semiconductor layer 101; a source region 103 of the second conductivity type (e.g. illustrated as an N+ region in FIG. 1) formed in the semiconductor layer 101 and separated from the well region 102 by a body region 30, wherein the source region 103 may have a heavier dopant concentration than the well region 102, and wherein the body region 30 may have the first conductivity type (e.g. illustrated as P-type in FIG. 1); a drain region 104 of the second conductivity type (e.g. illustrated as another N+ region in FIG. 1) formed in the well region 102 and separated from the source region 102, wherein the drain region 104 may have a heavier dopant concentration than the well region 102; a gate 105 positioned atop the semiconductor layer 101 near the source region 102 side; a field dielectric 106 positioned in or atop a portion of the well region 102 between the drain region 104 and the gate 105; a non-conductive field plate positioning layer 107 positioned atop a portion of the field dielectric 106 and separated laterally from the gate with a first lateral distance W1; and a lateral conductive field plate 108 positioned atop the non-conductive field plate positioning layer 107.

The field plate positioning layer 107 is configured to adjust a field plate to semiconductor height D1, which may refer to a vertical distance D1 from a bottom surface 108B of the lateral conductive field plate 108 to a semiconductor top surface 101T of the semiconductor layer 101 located under the lateral conductive field plate 108 (in the example shown in FIG. 1, the semiconductor top surface 101T is the same as the bottom surface 106B of the field dielectric 106). The lateral conductive field plate 108 may be laterally separated from the gate 105 by a second lateral distance W2 to optimize an effect of reducing a surface electric field by the conductive field plate 108 and to help to improve an overall performance of the lateral transistor 100. The second lateral distance W2 may be larger or equal to the first lateral distance W1 (i.e. 0<W1≤W2). In an embodiment, the first lateral distance W1 may range from 0.05 μm˜0.45 μm, and the second lateral distance W2 may range from 0.1 μm˜0.5 μm. In an embodiment, the first lateral distance W1 may range from 0.1 μm˜0.35 μm, and the second lateral distance W2 may range from 0.15 μm˜0.3 μm. In and embodiment, a difference (W2−W1) between the second lateral distance W2 and the first lateral distance W1 may range from 0 μm˜0.2 μm, or in an alternative embodiment, may range from 0.05˜0.1 μm. The lateral conductive field plate is “lateral” in that it has a lateral field plate width W108 larger than its vertical field plate thickness d108 (W108>d108).

In the exemplary embodiment shown in FIG. 1, the field plate to semiconductor height D1 may be determined by a vertical thickness d1 of the field plate positioning layer 107 and a vertical thickness/depth d2 of the field dielectric 106. Typically, during the fabrication process for manufacturing the lateral transistor 100, the field dielectric 106 (if any) is formed prior to the lateral conductive field plate 108 and the vertical thickness/depth d2 of the field dielectric 106 is somehow fixed to meet the requirements in e.g. breakdown voltage (BV), on resistance (Ron), specific on resistance (Ron*A), current handling capability etc. Therefore, without the field plate positioning layer 107, it is hard or unable to adjust the field plate to semiconductor height D1. However, in state of the art, it is desirable to be able to properly control the field plate to semiconductor height D1 since for high voltage DMOS, it is desirable to have the lateral conductive field plate 108 further away from the semiconductor top surface 101T but not too far away to effectively play its effect on reducing the surface electric field. The lateral transistor 100 in accordance with various embodiments of the present invention allows to flexibly control/adjust the field plate to semiconductor height D1 by modifying the vertical thickness d1 of the field plate positioning layer 107.

In accordance with an embodiment of the present invention, the non-conductive field plate positioning layer 107 may comprise a non-conductive layer having different etching characteristics (e.g. different etching rate, different etching selectivity etc.) from the field dielectric 106. For instance, the non-conductive positioning layer 107 may be etched while the field dielectric 106 is relatively etching resistive under the same etching process (e.g. either a wet etching process or a plasma etching process or any other appropriate etching process that can be applied during fabrication of the lateral transistor 100). In an exemplary embodiment of the present invention, the field dielectric 106 may comprise a field oxide layer, which may be formed of, for example, an oxide layer group such as silicon dioxide (SiO2). For this situation, the non-conductive positioning layer 107 may comprise a non-conductive layer which is etching selective to the field oxide layer and which may be formed of, for example, a non-conductive nitride layer group such as silicon nitride (SiN, SixNy), or other semiconductor nitride etc. In an alternative example, the non-conductive positioning layer 107 may comprise a non-conductive layer which is etching selective to the field oxide layer and which may be formed of, for example, a non-conductive carbide layer group such as silicon carbide (SiC, SixCy), or other semiconductor carbide etc. In an alternative example, the non-conductive positioning layer 107 may comprise a non-conductive layer which is etching selective to the field oxide layer and which may be formed of, for example, a nitride oxide compound layer group such as silicon oxide nitride (SiOxNy) etc. Or in still an alternative example, the non-conductive positioning layer 107 may comprise a non-conductive layer which is etching selective to the field oxide layer and which may be formed of a multilayer containing two or more from the aforementioned nitride layer group, the carbide layer group, nitride oxide compound layer group and the group. One of ordinary skill in the art would understand that the materials/compositions of the non-conductive positioning layer 107 and the field dielectric 106 listed here are just examples for helping to better understand embodiments of the present invention and are not intended to be limiting.

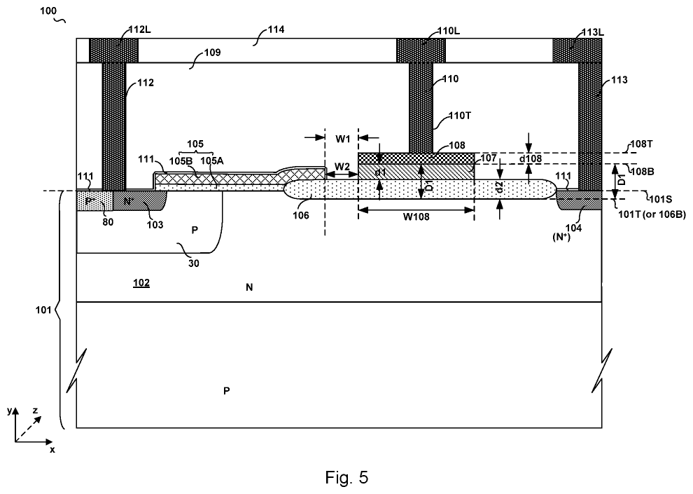

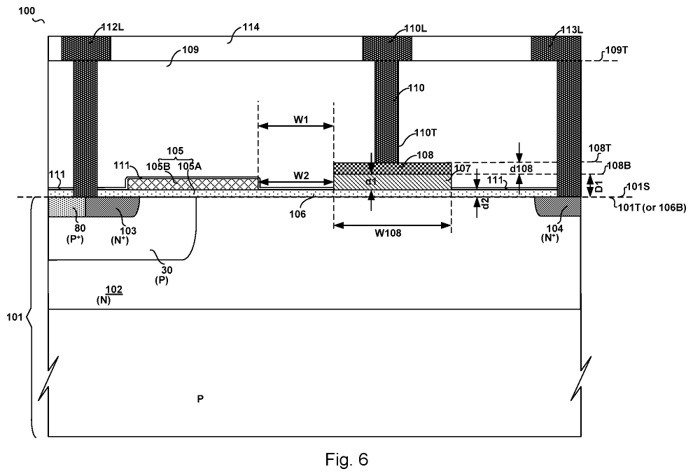

In accordance with an embodiment of the present invention, the lateral transistor 100 may further comprise an interlayer dielectric layer 109 coating the semiconductor layer 101 and the structures in/atop the semiconductor layer 101 (e.g. may include the gate 105, the field dielectric 106, the non-conductive field plate positioning layer 107, the lateral conductive field plate 108 etc. in the examples shown in FIGS. 1-6).

In accordance with an embodiment of the present invention, the lateral transistor 100 may further comprise a vertical trenched field plate contact 110 extending vertically from the top surface 109T of the interlayer dielectric layer 109 through the interlayer dielectric layer 109 to reach and contact with the lateral conductive field plate 108. The vertical trenched field plate contact 110 may be formed of highly conductive materials such as metals, alloy, and/or combinations thereof and may be disposed in a field plate contact trench 110T etched vertically through the dielectric layer 109. A vertical trenched source contact 112 and a vertical trenched drain contact 113 may be formed in the same process as the vertical trenched field plate contact 110 is formed. The vertical trenched source contact 112 extends vertically from the top surface 109T of the interlayer dielectric layer 109 through the interlayer dielectric layer 109 to reach and contact with the source region 103 and a body contact region 80 formed in the body region 30. The vertical trenched drain contact 113 extends vertically from the top surface 109T of the interlayer dielectric layer 109 through the interlayer dielectric layer 109 to reach and contact with the drain region 104. A second dielectric layer 114 disposed on top of the dielectric layer 109 may be formed to isolate a plurality of back-end-of-the-line (BEOL) metal wire layers 110L, 112L and 113L disposed in the second dielectric layer 114. The plurality of back-end-of-the-line (BEOL) metal wire layers 110L, 112L and 113L may respectively contact with the vertical trenched field plate contact 110, vertical trenched source contact 112 and the vertical trenched drain contact 113.

In accordance with an embodiment of the present invention, the lateral conductive field plate 108 may comprise a conductive layer having different etching characteristics (e.g. different etching rate, different etching selectivity etc.) from the interlayer dielectric layer 109 so that during an etching process to etch through the interlayer dielectric layer 109 to form the field plate contact trench 110T, etching can be effectively stopped at the top surface 108T of the lateral conductive field plate 108. That is to say, the lateral conductive field plate 108 can be meanwhile used as an etch stop layer when forming the field plate contact trench 110T.

In accordance with an embodiment of the present invention, the gate 105 may comprise a gate dielectric layer 105A and a gate conduction layer 105B sitting on the gate dielectric layer 105A. In an exemplary embodiment, the gate dielectric layer 105A may comprise a gate oxide layer, the gate conduction layer 105B may comprise a poly-silicon layer. In other embodiment, the gate conduction layer 105B may comprise other conductive materials (e.g., other semiconductors, semi-metals, and/or combinations thereof) that are compatible with other aspects of the device manufacturing process. Thus, the term “poly-silicon” is intended to include such other materials and material combinations in addition to silicon.

In accordance with an embodiment of the present invention, the lateral conductive field plate 108 may be formed in the same process as the gate conduction layer 105B is formed to simplify fabrication process and to save cost, and thus may have the same composition and the same vertical thickness as the gate conduction layer 105B.

In accordance with alternative embodiments of the present invention, the lateral conductive field plate 108 may be formed of any other conductive materials such as doped poly-silicon, metals (e.g. tungsten, titanium, cobalt etc.), alloy, metal nitride (TiN), metal carbide (e.g. TiC), other semiconductors, semi-metals, and/or combinations thereof.

In accordance with alternative embodiments of the present invention, the lateral conductive field plate 108 may not be formed in the same process as the gate conduction layer 1058 is formed, and may need to apply a dedicated mask layer to pattern and form the lateral conductive field plate 108.

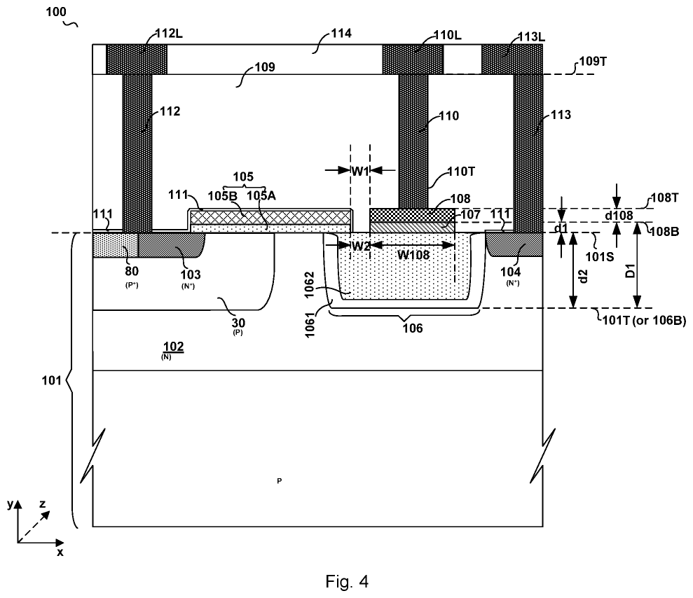

In an embodiment, the lateral conductive field plate 108 and the non-conductive field plate positioning layer 107 may have the same/similar etching characteristics and may share the same dedicated mask during an etching process to pattern and form both the lateral conductive field plate 108 and the non-conductive field plate positioning layer 107. For this exemplary situation, the non-conductive field plate positioning layer 107 and the lateral conductive field plate 108 may have the same pattern and lateral size, as illustrated in FIG. 4 to FIG. 6. For instance, the lateral conductive field plate 108 may be formed of a conductive nitride layer (e.g. metal nitride such as TiN) while the non-conductive field plate positioning layer 107 may be formed of a non-conductive nitride layer (e.g. semiconductor nitride such as SiN) and thus may be patterned and etched in the same etching process sharing one dedicated mask. To provide another example, the lateral conductive field plate 108 may be formed of a conductive carbide layer (e.g. metal carbide such as TiC) while the non-conductive field plate positioning layer 107 may be formed of a non-conductive carbide layer (e.g. semiconductor carbide such as SiC) and thus may be patterned and etched in the same etching process sharing one dedicated mask.

In accordance with an embodiment of the present invention, the field dielectric 106 may comprise a shallow trenched type field dielectric layer formed in a portion of the well region 102 between the drain region 104 and the gate 105, as illustrated in FIG. 1. The shallow trenched type field dielectric layer 106 may have a vertical thickness/depth d2. The shallow trenched type field dielectric layer 106 may be formed in a shallow trench opened from the top surface 101S of the semiconductor layer 101 and vertically extended into the well region 102, with a predetermined trench width W1 and a predetermined trench depth d2. The shallow trenched type field dielectric layer 106 may comprise a liner layer 1061 and an insulation layer 1062. The liner layer 1061 may coat the sidewalls and bottom of the shallow trench and may be formed through e.g. thermal oxidation or nitride deposition and may help to cure defects that have occurred during the process of etching the well region 102 to form the shallow trench. The insulation layer 1062 may be disposed in the shallow trench to fill the shallow trench and may be formed of for example, an oxide layer group such as silicon dioxide (SiO2), SOG (Spin On Glass), USG (Undoped Silicate Glass), BPSG (Boron Phosphorus Silicate Glass), PSG (Phosphor Silicate Glass), PETEOS (Plasma Enhanced Tetra Ethryl Ortho Silicate) and flowable oxide material or can be formed of a multilayer containing two or more from the oxide layer group.

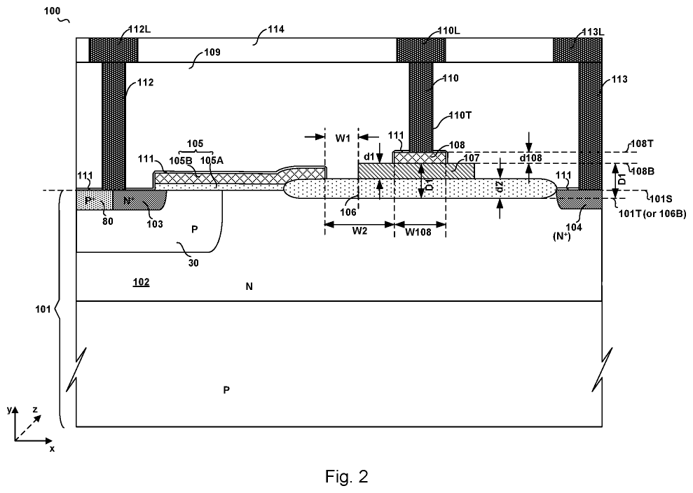

In accordance with an alternative embodiment of the present invention, the field dielectric 106 may comprise a thick field dielectric layer formed atop a portion of the well region 102 between the drain region 104 and the gate 105, as illustrated in FIG. 2. The thick field dielectric layer 106 may have a vertical thickness d2. The thick field dielectric layer 106 may comprise a thick oxide layer formed of for example, an oxide layer group such as silicon dioxide (SiO2), SOG (Spin On Glass), USG (Undoped Silicate Glass), BPSG (Boron Phosphorus Silicate Glass), PSG (Phosphor Silicate Glass), PETEOS (Plasma Enhanced Tetra Ethryl Ortho Silicate) and flowable oxide material or can be formed of a multilayer containing two or more from the oxide layer group.

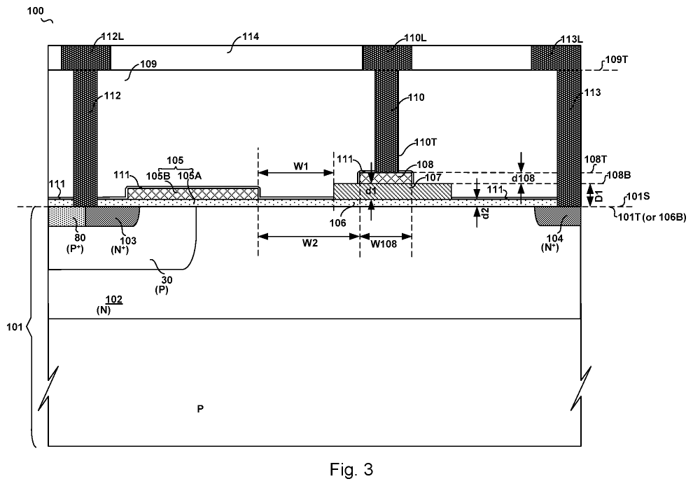

In accordance with still an alternative embodiment of the present invention, the field dielectric 106 may comprise a thin field dielectric layer formed atop a portion of the well region 102 between the drain region 104 and the gate 105, as illustrated in FIG. 3. To save cost and simplify the fabrication process, the thin field dielectric layer 106 in the example of FIG. 3 may be formed in the same process as the gate dielectric layer 105A is formed and thus may have the same composition as the gate dielectric layer 105A.

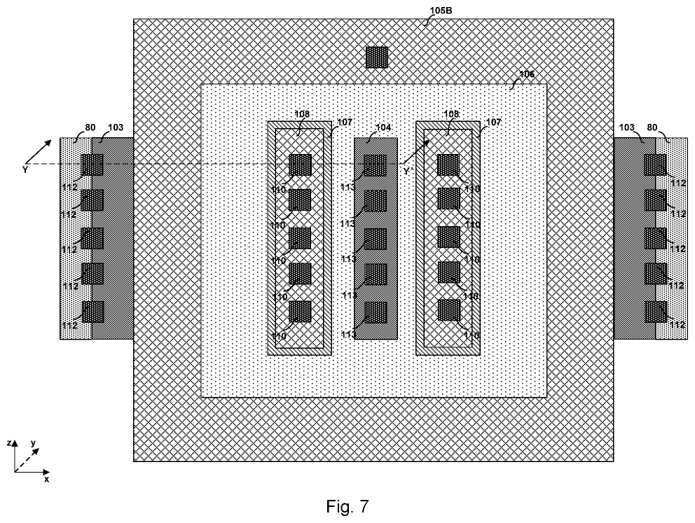

FIG. 7 illustrates a corresponding top plan view of the lateral transistor 100 shown in FIG. 1. Only the source region 103, the body contact region 80, the drain region 104, the gate conduction layer 105B, the dielectric 106, the non-conductive field plate positioning layer 107, the lateral conductive field plate 108, the vertical trenched field plate contact 110, the vertical trenched source contact 112, and the vertical trenched drain contact 113 are illustrated out in FIG. 7 to avoid obscuring aspects of the present invention. The top plan view is cut from a plane defined by the x axis and z axis. The cross-sectional view of the lateral transistor 100 shown in FIG. 1 corresponds to the portion cut down in the y axis from the cut line labeled with Y-Y′ in FIG. 7. The corresponding top plan views of the lateral transistor 100 shown in FIG. 2 and FIG. 2 are similar to that illustrated in FIG. 7 and will not be illustrated out herein. The vertical trenched field plate contact 110 may comprise a plurality of trenched contacts discontinuously distributed atop the lateral conductive field plate 108, as shown in FIG. 7. Alternatively, the vertical trenched field plate contact 110 may comprise one trenched contact continuously distributed atop the lateral conductive field plate 108.

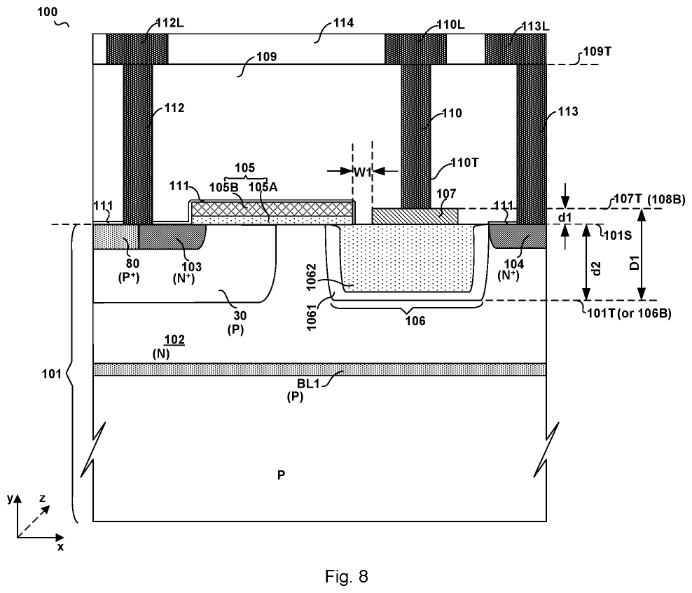

In accordance with an embodiment of the present invention, the lateral conductive field plate 108 may be omitted (i.e. may not be formed) and the vertical trenched field plate contact 110 may extend vertically from the top surface 109T of the interlayer dielectric layer 109 through the interlayer dielectric layer 109 to reach and contact with the non-conductive field plate positioning layer 107. As an example, FIG. 8 illustrates a cross-sectional view of the lateral transistor 100 shown in FIG. 1 with the lateral conductive field plate 108 omitted. One of ordinary skill in the art would understand that the cross-sectional views of the lateral transistor 100 shown in the embodiments of FIG. 2 to FIG. 6 with the lateral conductive field plate 108 omitted are similar to that illustrated in FIG. 8 and will not be illustrated out here. For this situation, the non-conductive field plate positioning layer 107 may comprise a non-conductive layer having different etching characteristics (e.g. different etching rate, different etching selectivity etc.) from both the field dielectric 106 and the interlayer dielectric layer 109. The non-conductive field plate positioning layer 107 is configured to adjust the field plate to semiconductor height D1 (i.e. the vertical distance D1 from the top surface 107T to the semiconductor top surface 101T of the semiconductor layer 101 since the top surface 107T should have been the same as the bottom surface 1086 of the lateral conductive field plate 108) and meanwhile to act as the etch stop layer when forming the field plate contact trench 110T so that etching of the interlayer dielectric layer 109 to form the field plate contact trench 110T can be effectively stopped at the top surface 107T of the non-conductive field plate positioning layer 107. For instance, the non-conductive field plate positioning layer 107 may be formed of non-conductive materials such as SiN or other semiconductor nitride that are etching resistive over both the field dielectric 106 and the interlayer dielectric layer 109 to an etchant.

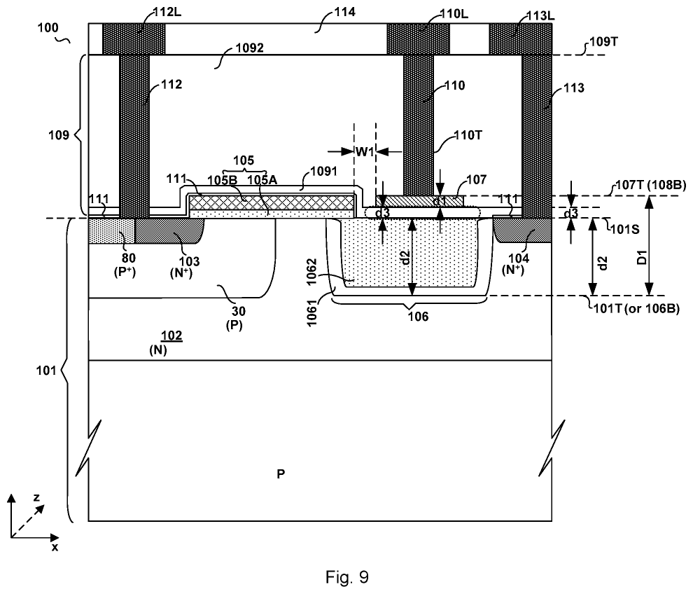

In accordance with an alternative embodiment of the present invention, as an exemplary variant of the embodiment illustrated in FIG. 8, a first partial layer 1091 which constitutes part of the interlayer dielectric layer 109 may be formed before forming the non-conductive field plate positioning layer 107, as illustrated in FIG. 9. The non-conductive field plate positioning layer 107 may sit atop a portion of the first partial layer 1091, as circled out with dashed line in FIG. 9, laterally located between the drain region 104 and the gate 105. The first partial layer 1091 may comprise a non-conductive layer having different etching characteristics (e.g. different etching rate, different etching selectivity etc.) from the non-conductive field plate positioning layer 107. The first partial layer 1091 of the interlayer dielectric layer 109 may have a vertical thickness d3 (e.g. ranging from 500 Å to 2000 Å). In such an variant embodiment, the non-conductive field plate positioning layer 107 and the first partial layer 1091 together can be used to adjust the field plate to semiconductor height D1 (D1=d1+d2+d3), which provides more flexible control of the field plate to semiconductor height D1 by modifying the vertical thickness d1 of the field plate positioning layer 107 and/or the vertical thickness d3 of the first partial layer 1091 of the interlayer dielectric layer. A second partial layer 1092 which constitutes the remained part of the interlayer dielectric layer 109 may be formed after the formation of the non-conductive field plate positioning layer 107, e.g. through deposition of a dielectric material having different etching characteristics (e.g. different etching rate, different etching selectivity etc.) from the non-conductive field plate positioning layer 107.

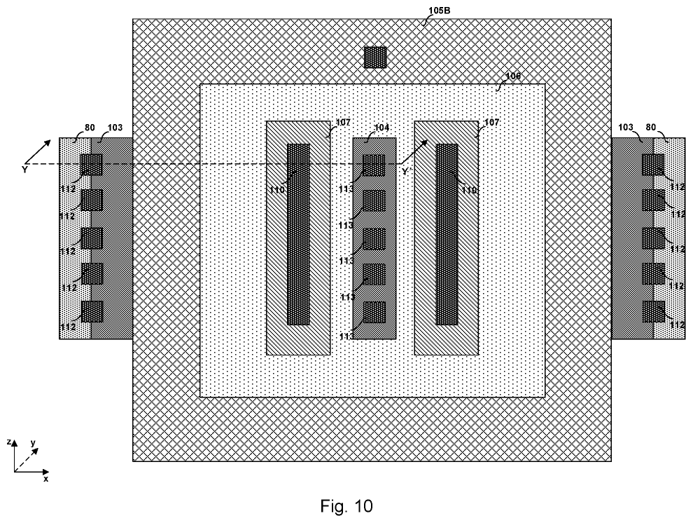

FIG. 10 illustrates a corresponding top plan view of the lateral transistor 100 shown in FIG. 8. Only the source region 103, the body contact region 80, the drain region 104, the gate conduction layer 105B, the dielectric 106, the non-conductive field plate positioning layer 107, the vertical trenched field plate contact 110, the vertical trenched source contact 112, and the vertical trenched drain contact 113 are illustrated out in FIG. 10 to avoid obscuring aspects of the present invention. The top plan view is cut from a plane defined by the x axis and z axis. The cross-sectional view of the lateral transistor 100 shown in FIG. 10 corresponds to the portion cut down in the y axis from the cut line labeled with Y-Y′ in FIG. 8. In such embodiments wherein the lateral conductive field plate 108 is omitted, the vertical trenched field plate contact 110 should better be continuously distributed in the dielectric layer 109 in the z axis direction.

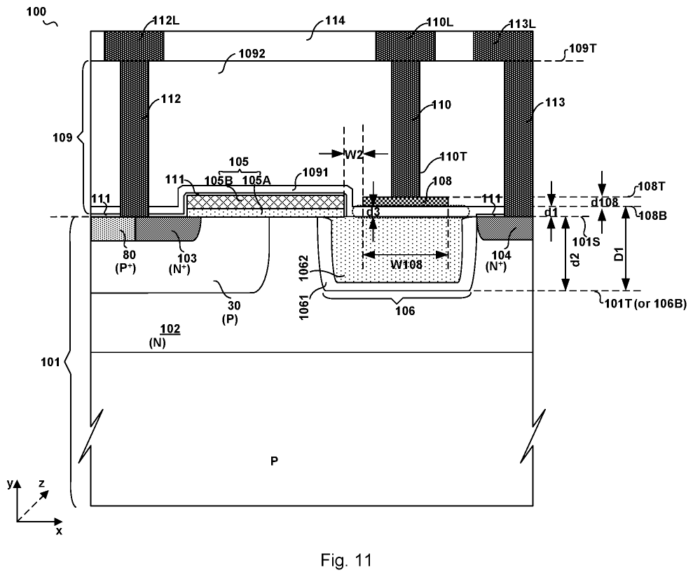

In accordance with an alternative embodiment of the present invention, as exemplary variants of the embodiments illustrated in FIG. 1 to FIG. 6, the non-conductive field plate positioning layer 107 may be omitted (may not be formed), a first partial layer 1091 which constitutes part of the interlayer dielectric layer 109 may be formed before forming the lateral conductive field plate 108, as illustrated in FIG. 11. The lateral conductive field plate 108 may sit atop a portion of the first partial layer 1091, as circled out with dashed line in FIG. 9, laterally located between the drain region 104 and the gate 105. The first partial layer 1091 may comprise a non-conductive layer having different etching characteristics (e.g. different etching rate, different etching selectivity etc.) from the lateral conductive field plate 108. The first partial layer 1091 of the interlayer dielectric layer 109 may have a vertical thickness d3 (e.g. ranging from 500 Å to 2000 Å). In such a variant embodiment, the first partial layer 1091 can be used to adjust the field plate to semiconductor height D1 (D1=d2+d3) by modifying the vertical thickness d3 of the first partial layer 1091 of the interlayer dielectric layer. The lateral conductive field plate 108 may be formed after the first partial layer 1091 of the interlayer dielectric layer 109 is deposited and may be patterned and etched using one dedicated mask without involving extra mask, etching process and cost in comparison with the embodiments shown in FIG. 1 to FIG. 6. A second partial layer 1092 which constitutes the remained part of the interlayer dielectric layer 109 may be formed after the formation of the lateral conductive field plate 108, e.g. through deposition of a dielectric material having different etching characteristics (e.g. different etching rate, different etching selectivity etc.) from the lateral conductive field plate 108.

Although lateral transistors are illustrated and explained based on a N channel lateral DMOS according to various embodiments of the present invention, but this is not intended to be limiting, and persons of ordinary skill in the art will understand that the processes, structures and principles taught herein may apply to other types of semiconductor devices having non-conductive field plate positioning layer and/or lateral conductive field plate with a vertical trenched field plate contact.

From the foregoing, it will be appreciated that specific embodiments of the present invention have been described herein for purposes of illustration, but that various modifications may be made without deviating from the invention. Many of the elements of one embodiment may be combined with other embodiments in addition to or in lieu of the elements of the other embodiments. Accordingly, the present invention is not limited except as by the appended claims.

I/We claim:

1. A lateral transistor, comprising:
a semiconductor layer of a first conductivity type;
a well region of a second conductivity type opposite to the first conductivity type formed in the semiconductor layer;
a source region of the second conductivity type formed in the semiconductor layer and separated from the well region by a body region;
a drain region of the second conductivity type formed in the well region and separated from the source region;
a gate positioned atop the semiconductor layer near the source region side;
a field dielectric positioned in or atop a portion of the well region between the drain region and the gate;
a non-conductive field plate positioning layer positioned atop a portion of the field dielectric and separated laterally from the gate with a first lateral distance, wherein the non-conductive field plate positioning layer has different etching characteristics from the field dielectric;
a lateral conductive field plate positioned atop the non-conductive field plate positioning layer and separated laterally from the gate with a second lateral distance;
an interlayer dielectric layer coating the semiconductor layer and the structures in/atop the semiconductor layer, wherein the interlayer dielectric layer has different etching characteristics from the lateral conductive field plate; and
a vertical trenched field plate contact extending vertically from a top surface of the interlayer dielectric layer through the interlayer dielectric layer to reach and contact with the lateral conductive field plate.

2. The lateral transistor of claim 1, wherein the non-conductive field plate positioning layer has a positioning layer vertical thickness configured to adjust a field plate to semiconductor height, and wherein the field plate to semiconductor height is a vertical distance from a bottom surface of the lateral conductive field plate to a semiconductor top surface of the semiconductor layer located under the lateral conductive field plate.

3. The lateral transistor of claim 2, wherein the positioning layer vertical thickness ranges from 300 Å to 3000 Å.

4. The lateral transistor of claim 2, wherein the positioning layer vertical thickness ranges from 500 Å to 2000 Å.

5. The lateral transistor of claim 1, wherein the non-conductive field plate positioning layer comprises a non-conductive layer formed of a non-conductive nitride layer group or a non-conductive carbide layer group or a nitride oxide compound layer group, or formed of a multilayer containing two or more from a non-conductive nitride layer group, a non-conductive carbide layer group and a nitride oxide compound layer group.

6. The lateral transistor of claim 1, wherein the second lateral distance is larger or equal to the first lateral distance.

7. The lateral transistor of claim 1, wherein the first lateral distance ranges from 0.05 μm˜0.45 μm.

8. The lateral transistor of claim 1, wherein the second lateral distance ranges from 0.1 μm˜0.5 μm.

9. The lateral transistor of claim 1, wherein the gate comprises a gate dielectric layer and a gate conduction layer sitting on the gate dielectric layer.

10. The lateral transistor of claim 9, wherein the lateral conductive field plate has the same composition and the same vertical thickness as the gate conduction layer.

11. The lateral transistor of claim 1, wherein the lateral conductive field plate has a field plate vertical thickness ranges from 100 Å to 200 Å

12. The lateral transistor of claim 1, wherein the lateral conductive field plate is formed of doped poly-silicon.

13. The lateral transistor of claim 1, wherein the lateral conductive field plate is formed of metal nitride.

14. The lateral transistor of claim 1, wherein the lateral conductive field plate is formed of metal carbide.

15. The lateral transistor of claim 1, wherein the lateral conductive field plate and the non-conductive field plate positioning layer have the same pattern and lateral size.

16. The lateral transistor of claim 15, wherein the lateral conductive field plate and the non-conductive field plate positioning layer have the same/similar etching characteristics and share a same dedicated mask during an etching process to pattern and form both the lateral conductive field plate and the non-conductive field plate positioning layer.

17. The lateral transistor of claim 15, wherein the lateral conductive field plate is formed of a conductive nitride layer, and wherein the non-conductive field plate positioning layer is formed of a non-conductive nitride layer and/or a non-conductive carbide layer.

18. The lateral transistor of claim 1, wherein the lateral conductive field plate is omitted, and wherein the vertical trenched field plate contact vertically extends to reach and contact with the non-conductive field plate positioning layer, and wherein the non-conductive field plate positioning layer is etching selective over both the field dielectric and the interlayer dielectric layer to an etchant.

19. The lateral transistor of claim 19, wherein a first partial layer which constitutes part of the interlayer dielectric layer is formed before forming the non-conductive field plate positioning layer, and wherein the non-conductive field plate positioning layer sits atop a portion of the first partial layer laterally located between the drain region and the gate.

20. The lateral transistor of claim 1, wherein the non-conductive field plate positioning layer is omitted, and wherein a first partial layer which constitutes part of the interlayer dielectric layer is formed before forming the lateral conductive field plate, and wherein the lateral conductive field plate sits atop a portion of the first partial layer laterally located between the drain region and the gate.
